(19) United States
(12) Patent Application Publication
(10) Pub. No.: US 2010/0066433 A1
(43) Pub. Date: Mar. 18, 2010

(54) BIAS CONTROLLER

(75) Inventor: Ryo MOCHIZUKI, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/507,443

(22) Filed: Jul. 22, 2009

(30) Foreign Application Priority Data
Sep. 17, 2008 (JP) 2008-238329

(51) Int. Cl. H01L 35/00

(52) U.S. Cl. 327/512

(57) ABSTRACT

A bias controller which can adjust a bias voltage of a FET without accidentally setting the bias voltage to a voltage which damages the FET, is provided. The bias controller includes temperature detector 351 configured to detect ambient temperature of FET (Field Effect Transistor) 12, 1st voltage generator 2 configured to generate a voltage signal for temperature compensating of a positive voltage based on an output of temperature detector 351, 2nd voltage generator 3 configured to generate a bias voltage signal of a positive voltage, and operational amplifier 33 and 34. Each operational amplifier 33 and 34 is individually configured to add the voltage signal for temperature compensation and the bias voltage signal, and to perform inverting amplification to generate the bias voltage of negative voltage to be applied to FET 12 and 22.

### CROSS REFERENCE TO RELATED APPLICATION

This application is based upon and claims the benefit of priority of Japanese Patent Application No. 2008-238329, filed on Sep. 17, 2008, the entire contents of which are incorporated herein by reference.

### FIELD OF THE INVENTION

This invention relates to a bias controller suitable for a power amplifier using FET used for a satellite base station, for example.

### DESCRIPTION OF THE BACKGROUND

A satellite base station uses a power amplifier which amplifies a modulated signal to transmission power. When the power amplifier uses a plurality of FETs (Field Effect Transistor), it is required to adjust a bias voltage of each FET. In order to adjust the bias voltage, it is necessary to adjust the bias voltage for each FET separately while considering the specific temperature characteristics of each FET.

Gallium nitride (GaN) and gallium arsenide (GaAs) are used for the above-mentioned FET as a semiconductor material. This FET is a depression type FET in which drain current flows even when a gate bias is not applied and the pinch off voltage is negative voltage. If the gate bias becomes zero potential or a positive voltage, an over-current will flow into the drain, a junction temperature in the FET will rise, and destruction of the FET will be caused. Therefore, the gate bias circuit needs to always supply negative voltage to the FET while working.

Japanese patent application publication No. 2003-8385 discloses a bias circuit with a temperature compensation function. This bias circuit performs temperature compensation by changing a bias voltage of an FET using a temperature detector, such as a thermistor.

However, even if the bias circuit with this temperature compensation function is used, it is fully expected that the bias circuit will be in the uncontrollable state, called a runaway state, and abnormalities, such as interference (cross modulation) to a signal from a temperature detector, occur. In such case, the gate bias may be set to a voltage which damages FET by heat generation by own drain current.

### SUMMARY OF THE INVENTION

A purpose of this invention is to provide a bias controller which can perform bias compensation of FET, without setting accidentally the gate bias to the voltage which damages the FET.

A bias controller according to the embodiment includes a temperature detector configured to detect ambient temperature of a depression type FET (Field Effect Transistor), a 1st voltage generator configured to generate a positive voltage signal for temperature compensation based on the output of the temperature detector, a 2nd voltage generator configured to generate a positive bias voltage signal, and an operational amplifier configured to add the voltage signal for temperature compensation and the bias voltage signal and additionally to perform inverting amplification to generate a bias voltage of negative voltage to be applied to said FET.

A bias controller for controlling bias of a plurality of depression type FETs (Field Effect Transistor) according to the embodiment includes a temperature detector configured to detect ambient temperature of the plurality of FETs, a 1st voltage generator configured to generate a positive voltage signal for temperature compensation common to the plurality of FETs based on the output of a temperature detector, a 2nd voltage generator configured to generate individual bias positive voltage signal for each FET separately, and a plurality of operational amplifiers, each of the operational amplifier being provided for each FET and being configured to add the voltage signal for temperature compensation and the individual bias voltage signal and to perform inverting amplification to generate a bias voltage of negative voltage to be applied to each said FET.

### BRIEF DESCRIPTION OF THE DRAWINGS

FIG. 1 is a block diagram showing the composition of a power amplifier with which a bias controller according to the embodiment is applied.

FIG. 2 is a circuit block diagram showing the composition of a control unit shown in FIG. 1.

### DETAILED DESCRIPTION OF THE INVENTION

Hereinafter, a bias controller according to an embodiment of this invention will be explained in detail with reference to the drawings.

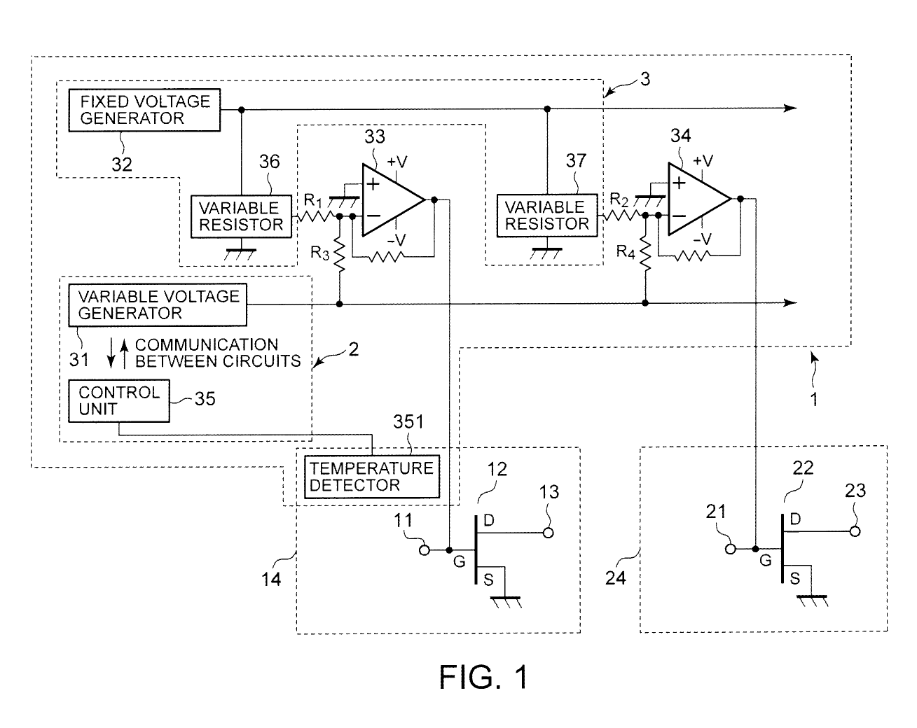

FIG. 1 is a block diagram showing the composition of a power amplifier with which the bias controller according to the embodiment is applied.

The high power solid state power amplifier using a plurality of FETs 12 and 22 which has a bias controller 1 is shown in FIG. 1. FETs 12 and 22 are depression type FETs which use gallium nitride or a material similar in ability. In order to obtain sufficient isolation between each FET 12 and 22, each amplifier module which uses FET 12 or 22 is placed individually in metal housing 14 and 24 for electromagnetic shielding.

An RF (Radio frequency) signal which should be amplified is supplied to input terminal 11, power of the RF signal is amplified by FET 12, and amplified signal power is outputted from output terminal 13. Similarly, the RF signal is supplied to input terminal 21, power of the RF signal is amplified by FET 22, and amplified signal power is outputted from output terminal 23.

The gate bias voltages of FETs 12 and 22 are generated by bias controller 1, and are applied to gates G of FETs 12 and 22.

Gate bias controller 1 has temperature detector 351, 1st voltage generator 2, 2nd voltage generator 3, and operational amplifier 33 and 34. 1st voltage generator 2 generates a voltage signal for temperature compensation of a positive voltage based on an output of temperature detector 351. 2nd voltage generator 3 generates a bias voltage signal of a positive voltage. Operational amplifier 33 and 34 adds the voltage signal for temperature compensation and the bias voltage signal and performs inverting amplification.

Temperature detector 351 detects ambient temperature of FET 12 or 22. Since the ambient temperature of FET 12 and the ambient temperature of FET 22 are generally identical, temperature detector 351 is arranged near FETs 12 or 22. In the embodiment, temperature detector 351 is installed in metal housing 14 and near FET 12. Bias controller 1 is arranged outside of metal housing 14, while temperature detector 351 is located inside metal housing 14.

2nd voltage generator 3 includes fixed voltage generator 32 and variable resistors 36 and 37.

Fixed voltage generator 32 has a fixed voltage generation circuit, and generates the predetermined positive voltage used as a baseline for determination. This positive voltage is divided by variable resistors 36 and 37, and bias voltage signals are generated. The bias voltage signal is supplied to an inverting input terminal of operational amplifier 33 and 34 via resistor R1 and R2, respectively. As for variable resistor 36 and 37, one end is connected to an output of fixed voltage generator 32, the other end is grounded, and a slide terminal outputs a divided voltage. The voltage of the bias voltage signal can be set up arbitrarily according to the position of the slide terminal, and thereby the bias voltage given to each FET 12 and 22 can be set individually.

Fixed voltage generator 32 may have a variable voltage generation circuit adjusted to output a predetermined positive voltage. Fixed voltage generator 32 is common to variable resistors 36 and 37, however, fixed voltage generator 32 may be individually formed to variable resistors 36 or 37.

1st voltage generator 2 includes variable voltage generator 31 and control unit 35.

Variable voltage generator 31 includes a digital/analog (D/A) converter (not shown), and generates a voltage signal for temperature compensation of the positive voltage according to the compensation data according to the ambient temperature of FETs 12 or 22 transmitted from control unit 35. The voltage signal for temperature compensation is supplied to the inverting input terminal of operational amplifier 33 and 34 via resistor R3 and R4, respectively.

Both variable voltage generator 31 and fixed voltage generator 32 operate with positive voltage of a power supply.

Operational amplifier 33 and 34 adds the bias voltage signal and the voltage signal for temperature compensation and performs inverting amplification to generate the negative gate bias voltage. This gate bias voltage is supplied to gate G of FET 12 and 22, respectively.

Control unit 35 transmits the compensation data according to the ambient temperature of FETs 12 and 22 to variable voltage generator 31.

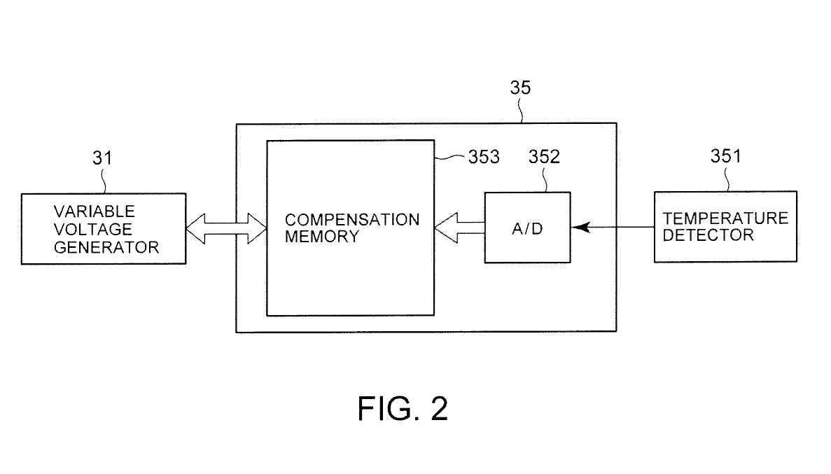

FIG. 2 is a circuit block diagram showing the composition of control unit 35. Control unit 35 includes analog/digital (A/D) converter 352, and compensation memory 353.

Temperature detector 351 includes a thermistor that detects the ambient temperature of FETs 12 and 22, and outputs a voltage according to the temperature detected as a temperature signal. Temperature detector 351 is placed near FET 12 in metal housing 14 as mentioned above. The temperature signal is inputted into control unit 35 by a cable. In control unit 35, analog/digital converter 352 changes the temperature signal into a digital value, and outputs digital temperature data. The digital temperature data is given to compensation memory 353 as address data.

Compensation memory 353 memorizes compensation data relating with each temperature value of a minute interval in a change range of ambient temperature (for example, 0 deg C.-70 deg C.). The compensation data determines the voltage value of the voltage signal for temperature compensation which variable voltage generator 31 generates.

Compensation memory 353 reads out the compensation data corresponding to the temperature which is detected by temperature detector 351, using the digital temperature data as the address data. Compensation memory 353 communicates with variable voltage generator 31 using a communication interface (for example, I2C (Inter-Integrated Circuit)), and transmits the compensation data read out to variable voltage generator 31. Variable voltage generator 31 generates the voltage signal for temperature compensation of the positive voltage corresponding to the compensation data with a digital/analog converter (not shown, but incorporated herein). Thus, the voltage signal for temperature compensation corresponding to the ambient temperature of FETs 12 or 22 is generated.

Next, adjustment of the bias voltage of FETs 12 and 22 in bias controller 1 of the above-mentioned composition is explained.

Although FETs 12 and 22 are FETs composed of identical material, the gate bias voltage values which set up the idle current of the drain differ for each FET. For this reason, in the embodiment, 2nd voltage generator 3 generates the bias voltage signal for each FET. That is, the positive voltage of the bias voltage signal inputted into each operational amplifier 33 and 34 is adjusted by each FET 12 or 22 by passing the positive voltage which fixed voltage generator 32 generates through variable resistor 36 or 37.

1st voltage generator 2 generates the voltage signal for temperature compensation of the positive voltage based on the output of temperature detector 351 as a temperature compensation function. That is, variable voltage generator 31 generates the voltage signal for temperature compensation according to the ambient temperature of FETs 12 or 24 as detected by temperature detector 351. The gate bias voltage value changes with the change of the voltage signal for temperature compensation. Since the characteristic curve of gate bias voltage—temperature originates in the material of the semiconductor, the individual difference is small between FETs 12 and 22 of the same material. Therefore, in the embodiment, the same temperature compensation voltage is applied to FETs 12 and 22.

Variable voltage generator 31 generates the voltage signal for temperature compensation of the voltage according to the temperature based on the compensation data transmitted from control unit 35. Variable voltage generator 31 is configured to generate the voltage signal for temperature compensation of a range of Vmin-Vdd by the digital/analog (D/A) converter which uses a digital potentiometer, for example. Fixed voltage generator 32 and variable resistor 36 and 37 can produce the bias voltage signal of 0V-Vdd according to the selected position of the sliding contactor of variable resistor 36 or 37. Here, Vmin is the minimum voltage of the positive voltage which variable voltage generator 31 can output, and Vdd is the operating voltage of variable voltage generator 31 and fixed voltage generator 32.

When operational amplifier 33 and 34 with amplification factor of −1.00 time adds both the voltage signal and the bias voltage signal and performs inverting amplification, an output voltage range is −Vmin-−2 Vdd.

Even if variable voltage generator 31 generates the voltage signal for temperature compensation of a wrong voltage by a runaway of control unit 35, interference (cross modulation) to the signal which connects temperature detector 351 and control unit 35, etc., the negative voltage below −Vmin will certainly be applied to each gate electrode of FET 12 or 22. For this reason, the gate becomes neither zero potential nor a positive voltage. Thereby, FETs 12 and 22 are prevented from being damaged by the rise of the junction temperature by the over-current of the drain.

Since variable voltage generator 31 outputs a voltage higher than Vmin, even if the output voltage from variable resistor R1 or R2 is set to zero potential accidentally during fine adjustment of the bias corresponding to each FET 12 and 22, the bias voltage supplied to the gate of each FET 12 and 22 is below −Vmin. For this reason, FETs 12 and 22 are prevented from being damaged by the rise of the junction temperature caused by the over-current of the drain.

In the embodiment, variable voltage generator 31 uses an integrated circuit for generating a variable voltage which operates with the positive voltage. This integrated circuit is easier to obtain and fits together better with control unit 35 than an integrated circuit for generating a variable voltage of negative voltage. This integrated circuit can generate output voltage (the voltage signal for temperature compensation) with high stability which fills the requirement of each FET 12 and 22.

With bias controller 1 of the embodiment as mentioned above, variable voltage generator 31 of 1st voltage generator 2 generates the voltage signal for temperature compensation of the voltage higher than Vmin common to FETs 12 and 22. In addition to this voltage signal for temperature compensation, 2nd voltage generator 3 generates a different bias voltage signals beyond 0V for each FET 12 and 22. Each operational amplifier 33 and 34 generates the bias voltage for each FET 12 and 22 by adding the voltage signal for temperature compensation and the bias voltage signal and performing inverting amplification.

Therefore, even if abnormalities occur in the voltage signal for temperature compensation, the bias voltage becomes below −Vmin and is prevented from being set to the voltage which damages FET 12 or 22. The bias of FET 12 or 22 is prevented from being accidentally set to zero potential or positive potential during adjustment of the bias voltage corresponding to each FET 12 and 22.

Furthermore, a general-purpose integrated circuit of positive voltage operation can be used for variable voltage generator 31 and fixed voltage generator 32 by adding the voltage signal and the bias voltage signal and performing inverting amplification by operational amplifier 33 or 34.

As explained above, according to this invention, the bias controller which can adjust the bias of the FET without setting accidentally the bias voltage to the voltage which damages the FET is provided.

The above-mentioned embodiment explains the example which adjusts the gate bias voltages for two FETs 12 and 22, the present invention, however, is applicable also to the bias controller which adjusts the gate bias voltages for three or more FETs. The present invention is applicable also to the bias controller of the amplifier which uses only one FET.

The bias controller of the present invention may include a temperature detector, a control unit and a variable voltage generator for each FET, respectively. In this case, the bias controller can apply an optimal bias voltage individually compensated for each FET to each FET.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A bias controller, comprising:
a temperature detector configured to detect ambient temperature of a depression type FET (Field Effect Transistor);
a 1st voltage generator configured to generate a voltage signal for temperature compensation of the positive voltage based on an output of said temperature detector;
a 2nd voltage generator configured to generate a bias voltage signal of a positive voltage; and
an operational amplifier configured to add said voltage signal for temperature compensation and said bias voltage signal and to perform inverting amplification to generate a bias voltage of negative voltage to be applied to said FET.

2. The bias controller according to claim 1, wherein said 2nd voltage generator has a fixed voltage generator which generates a predetermined voltage and a variable resistor which is intervened between said fixed voltage generator and said operational amplifier and is configured to divide an inputted voltage and to output a divided voltage.

3. The bias controller according to claim 1, wherein said FET amplifies electric power of an RF signal.

4. The bias controller according to claim 1, wherein an amplification factor of said operational amplifier is −1.

5. The bias controller according to claim 1, wherein said 1st voltage generator operates with a positive voltage and said 2nd voltage generator operates with a positive voltage.

6. The bias controller according to claim 1, wherein said FET is placed in a metal housing, said temperature detector is placed in said metal housing, and said 1st voltage generator is provided outside of said metal housing.

7. A bias controller for controlling bias of a plurality of depression type FETs (Field Effect Transistor), the bias controller comprising:
a temperature detector configured to detect ambient temperature of said plurality of FETs;
a 1st voltage generator configured to generate a voltage signal for temperature compensation of a positive voltage common to said plurality of FETs based on an output of said temperature detector;
a 2nd voltage generator configured to generate individual bias voltage signal of a positive voltage for each said FET; and
a plurality of operational amplifiers, each said operational amplifier being provided for each said FET and being configured to add said voltage signal for temperature compensation and said individual bias voltage signal and to perform inverting amplification to generate a bias voltage of negative voltage to be applied to each said FET.

8. The bias controller according to claim 7, wherein said 2nd voltage generator has a variable resistor configured to divide an predetermined voltage inputted and to output a voltage as said individual bias voltage signal for each said FET.

9. The bias controller according to claim 8, wherein said 2nd voltage generator has a fixed voltage generator configured to supply said predetermined voltage common to said variable resistor provided for each said FET.
